(19) United States
(12) Patent Application Publication
(10) Pub. No.: US 2008/0048681 A1
(43) Pub. Date: Feb. 28, 2008

(54) Device for Determining the State of a Soot Particle Filter

(75) Inventors: Thomas Birkhofer, Immenstaad (DE); Aleksandar Knezevic, Friedrichshafen (DE); Ralf Mueller, Deggenhausertal (DE); Carsten Plog, Markdorf (DE)

Correspondence Address: CROWELL & MORING LLP;INTELLECTUAL PROPERTY GROUP, P.O. BOX 14300, WASHINGTON, DC, 20044-4300, US

(73) Assignee: DaimlerChrysler AG, Muenchen (DE)

(21) Appl. No.: 10/589,231

(22) PCT Filed: Feb. 10, 2005
(86) PCT No.: PCT/EP05/01339

§ 371 Date: Apr. 17, 2007

(30) Foreign Application Priority Data
Feb. 12, 2004 (DE) 10 2004 007 038.5
Feb. 12, 2004 (DE) 10 2004 007 039.3
Feb. 12, 2004 (DE) 10 2004 007 040.7
Feb. 12, 2004 (DE) 10 2004 007 041.5

(51) Int. Cl. G01R 27/00

(52) U.S. Cl. 324/693

(57) ABSTRACT

A device determined the state of a soot particle filter of an internal combustion engine. An electrical measuring arrangement is embodied as a soot sensor for measuring a soot deposit and comprises an electrical component with a conductor structure for exciting an electrical or magnetic field which can be influenced by the soot deposit and characterizes an electrical or magnetic characteristic variable of the component. A measuring arrangement measures the electrical or magnetic characteristic variable of the component as a measure of the soot deposit. The conductor structure is arranged so that a partial volume region of the soot particle filter is penetrated by the electrical field, and the partial volume region forms part of the component.

This application is a National Stage of PCT/EP2005/001339, filed Feb. 10, 2005, which claims the priority of DE 10 2004 007 038.5, filed Feb. 12, 2004; DE 10 2004 007 039.3, filed Feb. 12, 2004; DE 10 2004 007 040.7, filed Feb. 12, 2004; and DE 10 2004 007 041.5, filed Feb. 12, 2004, the disclosures of which are expressly incorporated by reference herein.

### BACKGROUND AND SUMMARY OF THE INVENTION

The present invention relates to a device for determining the state of a soot particle filter of an internal combustion engine.

U.S. Pat. No. 4,656,832 discloses that, in order to determine the soot charge of a particle filter, an electrode arrangement is provided on a planar, nonconductive substrate and the entire arrangement is positioned in the exhaust gas path, if appropriate also in the interior of a particle filter. Soot particles which are deposited on the substrate reduce the electrical resistance which can be measured between the electrodes to determine the soot particle deposit on the substrate. The time for regeneration of the particle filter is derived therefrom.

The measurement of the soot charge on a planar reference region does not, however, make it possible to detect the charge state of the particle filter with the desired accuracy and to operate the particle filter in an optimum way.

WO 93/05388 discloses a soot sensor which is composed of a transmission antenna and a reception antenna. Through transmission losses of the transmission signal which migrates through the body of the soot filter are adopted as a measure for the soot charge. Such a soot sensor is, however, very complex and costly, especially since the transmission signal is a microwave signal.

DE 19933988 A1 and EP 587146 disclose devices for determining the soot charge of a soot particle filter in which the soot charge is derived from the difference in pressure between the input side and output side of the particle filter. Because the differential pressure depends not only on the charge state of the particle filter but also on the ash charge and gas flow through the filter, however, the measuring accuracy has been unsatisfactory until now.

EP 1106996 A2 describes a soot sensor in which a substrate which is subjected to the soot-containing gas is heated to the ignition temperature of the soot at defined time intervals. The quantity of heat which is then released and measured serves as a measure of the soot charge. Furthermore, DE 3525755 C1 discloses an optical measuring method which supplies a soot-dependent signal on the basis of the clouding of the exhaust gas which is caused by soot and the optical distance which is changed as a result. These two measuring methods are not suitable for direct detection of the charge of soot particle filters.

An object of the present invention is to provide a device for determining soot deposits which is suitable for soot particle filters in motor vehicles and which is easy and cost-effective to implement and largely immune to faults.

This object has been achieved according to the invention by a device in which the conductor structure is arranged in such a way that a partial volume region of the soot particle filter is penetrated by the electrical field and the partial volume region forms part of the component, wherein the electrical component is embodied as a coil or a capacitor.

The device according to the present invention is defined by the fact that soot deposits in the particle filter and therefore the charge of the particle filter can be measured in a three-dimensional, coherent partial volume region of the particle filter body. In this context, this partial volume region itself forms part of the component whose electrical or magnetic characteristic variable or characteristic variables can be measured by the associated measuring means. The field which is excited by the conductor structure can be of an electrical or magnetic nature here. The measuring arrangement is also capable of deriving the quantity of the soot deposits from the measured characteristic variable.

Because the soot deposit in the partial volume region influences the electrical or magnetic field which is excited by the conductor structure and thus the characteristic variable of the component, a particularly reliable determination, which is largely undisrupted by the respective flow conditions, of the charge is made possible. Regeneration of the particle filter can be triggered if the soot charge of the particle filter in the partial volume region has exceeded a predefinable upper limiting value.

The measurement of the particle filter charge in a partial region of the particle filter body which is extended in terms of volume permits, on one hand, a more differentiated evaluation of the charge state compared to an integral charge determination performed on the entire filter body. On the other hand, a most significant part of the particle filter can be measured which permits precise evaluation of the charge state and thus determination of an optimum time for triggering regeneration of a particle filter through the burning off of soot.

As a result of the foregoing, both unnecessary and delayed regenerations can be reliably avoided. The charge of the particle filter body is understood here to be the volume-related depositing of solid components such as soot or ash in its interior. The charge is preferably specified in grams per liter filter volume. The limiting value for the soot charge which is most significant for the triggering of the regeneration can be defined here as a function of the location where the charge is measured in the particle filter body, the ash charge which is present, the maximum tolerable release of heat during the burning off of the soot during regeneration or as a function of other, possibly motor-related operating variables. Mainly porous shaped bodies or monolithic shaped bodies permeated by ducts with porous walls are possible as soot particle filters.

In an embodiment of the invention, the soot deposit can be measured in partial volume regions of the soot particle filter which are different from one another. In this context, separate measuring arrangements which are effective as soot sensors are preferably provided for the respective partial volume regions. The partial volume regions preferably lie in the direction of the flow of exhaust gas with an offset with respect to one another. Since the charge of the particle filter is essentially dependent on the direction of flow of the exhaust gas, i.e., has an axial gradient, the local or axial profile of the charge in the particle filter can thus be determined. As a result, the charge state of the particle filter can be determined more precisely.

One advantage of the device according to the invention consists in particular in the fact that in a basic configuration only two robust measuring electrodes which are not prone to faults are required. Thereby, the measurement of the impedance between these measuring electrodes can take the form of a simple and cost-effective method which is not prone to faults either. In one form, the soot particle body or a partial volume region is itself the sensor which is provided with these measuring electrodes. In one particularly advantageous embodiment, a simple sensor which is appropriately embodied can be arranged downstream of the soot particle body. The electrical sensor signal is a direct measure of the soot charge and thus a measure of the state of the particle filter.

In one currently preferred embodiment, the measuring arrangement measures the ohmic resistance and/or the capacitance and/or the inductance. Furthermore, they can also advantageously measure the absolute value and the phase of the electrical impedance. An alternating current with a frequency in the kHz to MHz region is expediently used to measure the impedance.

Switching apparatus for automatically initiating the regeneration of the filter when a predefinable triggering measured value is reached have also proven particularly expedient. These and other switching devices can also be used for automatically ending the regeneration of the filter when a predefinable limiting measured value is reached. As a result, fully automatic regeneration of the filter can easily be carried out.

Since the measured values, that is to say the electrical characteristic variables, also depend on the temperature of the component or of the soot particle filter, temperature measuring devices are advantageously provided for measuring the temperature of the filter and for performing temperature compensation on the respective measurement signal. At least one temperature sensor is preferably provided as the temperature measuring devices and is expediently integrated on or in the conductor structure or at least one of the measuring electrodes which are present. For this purpose, the sensor is preferably embodied as a printed-on, temperature-dependent structure, in particular as a thick-film metal resistor. A further advantageous refinement consists in part of the conductor structure being of temperature-dependent configuration in order to form the temperature sensor.

In one advantageous refinement of the invention, a measurement arrangement which comprises a coil-shaped conductor structure is provided. The latter preferably surrounds at least a partial volume region of the particle filter. As a result, a component is formed whose inductance is a measure of the soot deposit. It is therefore provided that a variable which correlates to the permeability constant of the material present in the partial volume region and/or to the inductance of the coil-shaped conductor structure can be measured. In this context, the permeability constant is to be understood in particular to be the relative magnetic permeability which is usually designated by μr.

The conductor structure is preferably embodied as a cylindrical wire coil with a multiplicity of turns. The coil is wound at least around a partial section of the particle filter or is arranged in the interior of the particle filter which is embodied as a shaped body. Since the permeability constant depends on the type of material which is present in the volume region surrounded by the conductor structure, the charge state, i.e., the charge of the particle filter, can be determined reliably by means of a variable which correlates to the permeability constant and is measured by the conductor structure. As a result, both unnecessary and delayed regenerations can be reliably avoided.

In addition or as an alternative, the inductance of the conductor structure or a variable which correlates to the inductance of the conductor structure can be measured by the measuring arrangement. The volume region which is surrounded by the conductor structure acts as a coil core for the conductor structure. When the measuring arrangement is operating, an electric current flows through the conductor structure and excites a corresponding magnetic field. The induction which is caused by the magnetic field is linked to the magnetic field strength by the permeability constant of the material which is penetrated by the magnetic field. Since the inductance of the conductor structure is however linked to the induction, measuring the inductance of the conductor structure or measuring a variable which correlates thereto permits the charge in the most significant volume region of the particle filter also to be determined.

In a further aspect of the invention, the conductor structure is arranged at least partially in the interior of the particle filter. Since sufficient sensitivity of the measuring arrangement is to be aimed at, it is advantageous, due to the measuring effect, that the core of the coil-shaped conductor structure is filled as completely as possible by the material of the particle filter. It is therefore favorable to arrange the conductor structure completely in the interior of the particle filter. On the other hand, it may be advantageous, for example for practical reasons, if part of the conductor structure is arranged outside the particle filter body.

It is also advantageous, according to a further aspect of the invention, to arrange the coil-shaped conductor structure outside the particle filter and to wrap the conductor structure around the particle filter, for example in certain sections.

In a further refinement of the invention, the coil-shaped conductor structure is arranged so that its longitudinal axis is oriented approximately parallel to one of the main axes of the cylinder-shaped particle filter. It is advantageous to arrange the coil-shaped conductor structure in such that its longitudinal axis is oriented parallel with respect to the longitudinal axis of the particle filter, resulting in a simple configuration.

In a yet further refinement of the invention, the measuring arrangement comprises a second conductor structure, in which case the coil-shaped conductor structure is operatively connected to the second conductor structure, and the second conductor structure has an electrical characteristic variable which can be influenced by the soot deposit or the charge state of the particle filter and can be measured by the measuring arrangement. In this way, two different measurement signals can be obtained, which improves the reliability. On the other hand, it is advantageous to embody the two conductor structures in so that they interact with one another in the manner of a feedback made so that the sensitivity of the measuring arrangement is increased. The operative connection between the two conductor structures can be made here by an electrically conductive connection or by a wire free coupling.

The two conductor structures are preferably arranged at different locations. It is thus possible to determine the charge of the particle filter with soot and/or ash in at least two different partial volume regions of the particle filter and thus with spatial resolution. This permits the charge state to be evaluated accurately and thus allows an optimum time for triggering regeneration of a particle filter, for example by burning off soot, to be determined. As a result, both unnecessary and delayed regeneration processes can be reliably avoided.

It may be advantageous if the electrical characteristic variable of the second conductor structure which can be measured by the measuring arrangement is a capacitive or an inductive electrical characteristic variable. It is advantageous in particular to embody the coil-shaped conductor structure and the second conductor structure so that together they provide a resonant structure, which increases the sensitivity. The second conductor structure is preferably embodied as a capacitor for this purpose.

In a still further refinement of the invention, the second conductor structure is embodied as a second coil-shaped conductor structure and a variable which correlates to the mutual inductance which is effective between the conductor structures can be measured by the measuring arrangement. It is particularly advantageous to embody the conductor structures as coupled coils. Both the mutual inductance of the first with respect to the second conductor structure and the mutual inductance which is present in a rear form can be measured. The first or the second conductor structure here can also be arranged outside the particle filter so that they do not surround any part of the particle filter. On the other hand, the respective other conductor structure surrounds at least a partial volume region of the particle filter. The magnetic field of the conductor structure which is excited outside the particle filter and is preferably embodied as a coil can thus be defined by the measuring arrangement. However, the flow of the induction which is linked thereto through the partial volume of the particle filter which is surrounded by the other conductor structure is dependent on the charge present there. As a result, the charge of the particle filter can be reliably determined by measuring the mutual inductance or a variable which correlates to it.

According to another aspect of the invention, the coil-shaped conductor structure is arranged in the direction of flow of the exhaust gas with an offset with respect to the second conductor structure. This permits the soot charge of the particle filter to be determined with resolution in the axial direction. Since the charge of the particle filter is essentially dependent on the direction of flow of the exhaust gas, i.e., has an axial gradient, the axial profile of the charge in the particle filter can thus be determined. This permits particularly accurate determination of the charge state of the particle filter. The volume region in which the charge is respectively measured results from the geometry of the coil-shaped conductor structure, and in the case of a circular cylindrical coil results in particular from its diameter and length. The number of turns in a coil-shaped conductor structure allows the inductance of the coil-shaped conductor structure to be essentially determined at the same time.

In a still further refinement of the invention, a measuring arrangement is provided in which the conductor structure comprises a pair of electrodes with a first electrode and a second electrode which is arranged spaced apart from the first electrode. The electrodes of the pair of electrodes are arranged here in such a way that at least a partial volume region of the particle filter is located between them. Preferably, the electrical impedance which is effective between the first electrode and the second electrode or a characteristic variable which is linked thereto can be measured by the measuring means. Primarily, the absolute value of the impedance, and its real part and virtual part as well as its phase angle, are possible as characteristic variables which are linked to the impedance which is to be preferably considered as complex.

Since the impedance is dependent on the dielectric constant of the material present in the most significant partial volume region, and soot has, as an electrically conductive material, a dielectric constant which is higher than an insulator by an order of magnitude, the impedance of soot which is present and effective between the electrodes is greatly influenced. As a result, in particular in the case of a particle filter body which is embodied as an electrically insulating material such as ceramic, the charge state or the soot charge of the particle filter can be reliably determined by measuring the impedance which is effective between the electrodes of the pair of electrodes. As a result, both unnecessary and delayed regeneration processes can be reliably avoided.

In a further refinement of the invention, the first electrode and the second electrode are of planar design and are arranged opposite one another as plates of a plate capacitor. Preferably, the electrical capacitance of the arrangement composed of capacitor plates and particle filter volume lying between them is evaluated in order to measure the charge state, in particular the soot charge of the particle filter. The electrical capacitance is dependent on the type and quantity of the material present there. Because of the measuring arrangement according to the invention, the particle filter itself forms a sensor which is provided with electrodes and has the purpose of measuring the charge state of the particle filter. The measuring arrangement makes it possible to determine at least the soot charge in the volume region of the particle filter lying between the electrodes from the capacitance.

In a further embodiment of the invention, the first electrode and/or the second electrode are arranged on the outer surface of the particle filter or at a short distance from the outer surface of the particle filter. Depending on the shape of the particle filter, the electrodes can have a curved face in order, for example, to be able to follow the surface contour of a round or oval particle filter.

The electrodes are preferably arranged diametrically opposite one another and provided directly on the outer surface of the particle filter.

In yet another embodiment of the invention, the measuring arrangement comprises at least two pairs of electrodes. The charge of the particle filter with soot and/or ash can thus be determined in at least two, preferably different, partial volume regions of the particle filter, and thus determined with spatial resolution. This permits the charge state to be evaluated accurately, and thus allows an optimum time for triggering regeneration of a particle filter by the burning off of soot to be determined. As a result, both unnecessary and delayed regeneration processes can be reliably avoided.

Another aspect of the invention is that the first pair of electrodes is arranged in the flow of exhaust gas with an offset with respect to the second pair of electrodes. This permits the soot charge of the particle filter to be determined with resolution in the axial direction. Since the charge of the particle filter is essentially dependent on the direction of flow of exhaust gas, i.e., has an axial gradient, the axial profile of the charge in the particle filter can thus be determined. This permits particularly accurate determination of the charge state of the particle filter. The volume region in which the soot charge is measured in each case results from the geometry of the electrodes of the pair of electrodes, i.e., from the area of the respective electrodes and the distance between them, i.e., the diameter and the lateral dimensions of the particle filter at the respective location.

In a currently preferred embodiment integrated soot filter body, the at least one pair of electrodes is arranged directly on or in the soot filter body in the form of wires, small plates, applied areas or using thick film technology. In the embodiment integrated in the soot filter body, a pair of electrodes can be arranged in or on different ducts through the soot filter body or on its outside, in particular on the longitudinal outer sides and/or end faces.

In further embodiments of the invention it is also contemplated to arrange a plurality of pairs of electrodes next to one another in the axial direction and/or radial direction, for example even in a spiral-shaped arrangement. Spatial resolution of the soot charge of the soot filter body can also advantageously be achieved in conjunction with measuring devices of these plurality of pairs of electrodes.

In a further refinement of the invention, a second electrical measuring arrangement which is effective as a soot sensor for measuring a soot deposit is provided and is arranged downstream of the soot particle filter with respect to the direction of flow through the soot particle filter. This measuring arrangement expediently also has a conductor structure which is assigned to an electrical component so that the electrical characteristic variable or characteristic variables of the component are influenced by soot deposits, which is detected by appropriate measuring apparatuses. In this case of a separate soot filter sensor, an appropriate arrangement of the conductor structure is preferably on a substrate.

In the sensor which is arranged separately from the soot filter body, the substrate which is provided with the conductor structure, preferably a pair of electrodes, can be arranged downstream of the soot filter body or on its rear side with respect to the direction of flow through the soot particle filter. The pair of electrodes can be in the form of an interdigital electrode structure on the substrate which is embodied as a ceramic substrate. As an alternative to this, the temperature sensor can also be arranged under a measuring electrode or on the rear side of the substrate, separated by a dielectric.

According to the invention, the particle filter which is embodied as a shaped body can be assigned a measuring arrangement which comprises a coil-shaped conductor structure which surrounds at least a partial volume region of the particle filter. As a result, an electrical component is formed and a variable which correlates to the permeability constant of the material present in the partial volume region and/or to the inductance of the coil-shaped conductor structure is measured.

Likewise, in order to determine the charge state it is possible to assign a measuring arrangement which comprises a first electrode and a second electrode and the electrical impedance which is effective between the first electrode and the second electrode or an electrical characteristic variable which is linked thereto is measured. The shape of the volume region which is measured by the respective measuring arrangement is determined here essentially by the geometry of the conductor structure.

The charge of the particle filter is in turn determined from the respective measured variable. This is preferably carried out by a previously determined characteristic curve for the dependence of the measurement signal on the soot charge. In this context, secondary influences such as, for example, temperature dependencies in the form of characteristic diagrams can be taken into account.

If the conductor structure is embodied as a cylindrical coil, its inductance is preferably measured by suitable measuring apparatus. Since the inductance depends on the type of material which is effective as a coil core, the charge in the most significant volume region can be reliably determined by the material-dependent permeability constant.

If a first electrode and/or a second electrode are arranged on the outer surface of the particle filter or at a short distance from the outer surface of the particle filter, the electrical capacitance of the arrangement which is formed from the first electrode, second electrode and particle filter volume region arranged between the electrodes and which constitutes an electrical component is preferably determined and the soot charge of the particle filter is determined from the capacitance. As a result, the soot charge is determined at least in a portion of an approximately disk-shaped volume partial region of a cylindrical particle filter.

If it is determined that the soot charge which is derived from the measured characteristic variable exceeds a predefinable upper limiting value, the regeneration of the particle filter is triggered. This procedure permits the particle filter charge to be determined in a partial region of the particle filter body which extends as a volume, and thus on the one hand permits a differentiated evaluation of the charge state. On the other hand, a most significant part of the particle filter can be measured. Depending on the arrangement and orientation, the charge can be determined in virtually any region of the particle filter. This permits an optimum time for the triggering of regeneration of a particle filter, for example by the burning off of soot, to be determined. As a result, both unnecessary and delayed regeneration processes can be reliably avoided. The limiting value for the soot charge which is most significant for the triggering of the regeneration can be determined as a function of the location where the conductor structure is provided, the ash charge which is present, the maximum tolerable release of heat during the burning off of soot during the regeneration or as a function of other, possibly engine-related operating variables.

The soot charge of the particle filter is preferably determined by two or more conductor structures arranged in the direction of flow with an offset with respect to one another. As a result, the soot charge can be determined by two or more, possibly overlapping regions of the particle filter, and the regeneration of the particle filter is triggered if the soot charge in at least one of the measured partial volume regions of the particle filter has exceeded the predefinable upper limiting value. The duration of the regeneration is expediently adapted to the charge of the particle filter which is determined before the triggering of the regeneration. The consumption-intensive regeneration operating mode is only maintained in this way for as long as is necessary, which permits regeneration of the particle filter in a way which is particularly economical in terms of fuel consumption. When there are a plurality of measured partial volume regions it is particularly advantageous to adapt the duration of the regeneration of the particle filter to the maximum charge determined in one of the respective regions, permitting complete regeneration of the particle filter.

It is expedient to determine the soot charge of the particle filter after regeneration has taken place and to compare it with a predefinable setpoint value and to define the duration of a subsequent regeneration as a function of the result of the comparison. Thereby, the duration of the regeneration can be optimized. It is also advantageous to determine the soot charge directly before and directly after the regeneration. Moreover, the quality of the regeneration can be determined from the difference between the soot charges and the duration of subsequent regeneration processes can be determined in the measure of the most complete possible regeneration. It is advantageous to determine the success of a plurality of regeneration processes in the described way in order to obtain a statistically more reliable average value for the regeneration duration to be determined.

The present invention also permits the soot charge of the particle filter to be determined during the regeneration of the particle filter and for the regeneration to be ended if the charge drops below a predefinable lower limiting value. In particular, when the soot charge is determined at a plurality of locations, the progress of the regeneration can thus be pursued particularly accurately and the end of the regeneration can be determined reliably.

By measuring one or more electrical characteristic variables, it is possible, when determining the charge of the particle filter, to determine a soot charge component and an ash charge component. Since the permeability constants or dielectric constants of soot and of possibly iron-containing ash are different, it is possible to differentiate between the soot charge and the ash charge. This permits a further improved degree of accuracy when determining a suitable time for the regeneration of the particle filter since charge components which are made up of ash are not being incorrectly interpreted as soot charge.

It is advantageous to additionally measure an exhaust gas pressure upstream of the particle filter and to determine, from the measured exhaust gas pressure, a variable which correlates to the charge of the particle filter and to use it to correct or check of the determined soot charge. The reliability of the determined charge state of the particle filter can be improved by a pressure sensor or differential pressure sensor which is preferably arranged on the input side of the particle filter in the exhaust gas system. Furthermore, it is possible to carry out plausibility checking of the determined charges and to diagnose or standardize the measuring arrangement.

Other objects, advantages and novel features of the present invention will become apparent from the following detailed description of the invention when considered in conjunction with the accompanying drawings.

### BRIEF DESCRIPTION OF THE DRAWINGS

FIG. 1 is a schematic illustration of a soot particle filter with a separate soot sensor which is arranged downstream thereof in the flow direction,

FIG. 2 is a perspective view of the soot filter body of a corresponding soot particle filter with pairs of electrodes arranged on the longitudinal sides,

FIG. 3 is a schematic illustration explaining the measuring process,

FIG. 4 shows a further arrangement of a pair of electrodes which are arranged on two adjacent longitudinal sides of the soot filter body,

FIG. 5 shows a pair of electrodes which are arranged in the interior of the soot filter body,

FIG. 6 shows a further arrangement of a pair of electrodes which are arranged in the interior of the soot filter body,

FIG. 7 is a characteristic curve explaining the changing electrical resistance,

FIG. 8 is a characteristic curve explaining the changing capacitance,

FIG. 9 is two characteristic curves explaining the changing alternating current resistance at different frequencies,

FIG. 10 is a first schematic cross-sectional view of a soot particle filter with an associated arrangement of electrodes for determining a filter charge,

FIG. 11 is a second schematic cross-sectional view of a soot particle filter with associated arrangement of electrodes for determining a filter charge,

FIG. 12 is a schematic view of an electrode arrangement, developed onto a plane, for determining a filter charge,

FIG. 13 is a schematic perspective view of a soot particle filter component and an associated measuring arrangement for determining the filter charge,

FIG. 14 is a schematic cross-sectional view of the soot particle filter component as seen in FIG. 13 as well as an associated measuring arrangement for determining the filter charge,

FIG. 15 is a first schematic view of a soot particle filter with associated coil-shaped conductor structure for determining the filter charge,

FIG. 16 is a second schematic view of a soot particle filter with associated coil-shaped conductor structure for determining the filter charge, and

FIG. 17 is a diagram showing the relationship between the filter charge and an electrical characteristic variable which correlates thereto and is measured with measuring equipment.

### DETAILED DESCRIPTION OF THE DRAWINGS

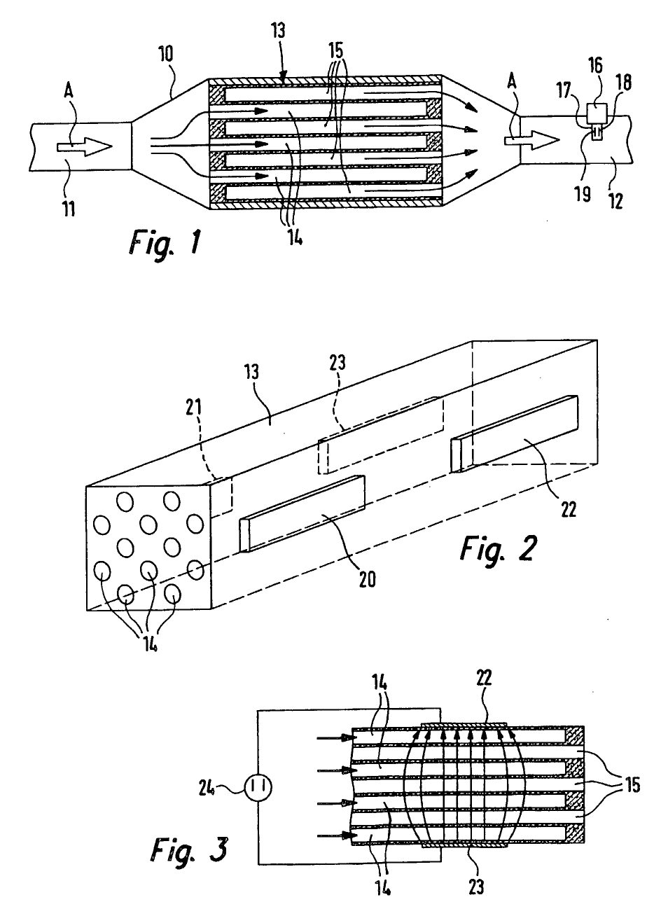

FIG. 1 is an illustration of a soot particle filter for motor vehicles, in particular for diesel vehicles. The filter has a housing 10 with an exhaust gas inlet 11 and an exhaust gas outlet 12. The housing 10 contains a soot filter body 13 composed of a ceramic filter material which has a multiplicity of blind ducts 14 which open on the inlet side and a multiplicity of blind ducts 15 which open on the outlet side. The exhaust gas enters the inlet-end blind ducts 14 and passes through the walls into the outlet-end blind ducts 15. In the process, the soot particles are filtered out through these walls.

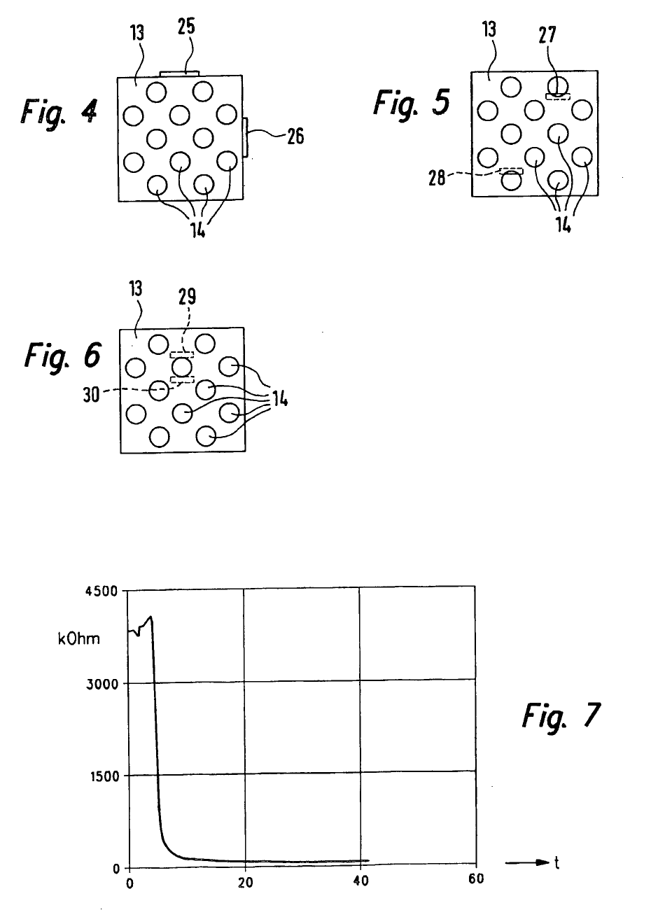

A soot sensor 16 is arranged in the exhaust gas outlet 12 downstream of the soot filter body 13 in the flow direction A. The sensor could in principle also be arranged closer to the soot filter body 13 or on its rear side. This soot sensor 16 is composed essentially of a ceramic substrate 17 in the form of a small plate, on which at least two measuring electrodes 18, 19 are provided. They can be provided, for example, using thick film technology, by painting on or spraying on or in the form of an interdigital electrode structure. Soot particles are deposited on the surface of the ceramic substrate 17 and thus change the electrical impedance between the measuring electrodes 18, 19. The changing impedance is a measure of the quantity of the deposited soot particles. This is explained in even more detail in conjunction with FIGS. 4 and 7 to 9. Not only the quality of the exhaust gas but also the state of the soot filter body 13, for example even a passage through this soot filter body, can be determined for this soot sensor 16.

In the embodiment illustrated in FIG. 2, two pairs of electrodes which are composed of measuring electrodes 20 to 23 are arranged on opposite longitudinal side faces of the soot filter body 13. These measuring electrodes 20 to 23 can be provided on the ceramic soot filter body 13 in the form, for example, of wires, small plates, applied surfaces or using thick film technology. In this exemplary embodiment, the soot filter body 13 itself serves as a sensor and the dependence of the electrical impedance between the measuring electrodes 20, 21 and 22, 23 on the charge of the soot filter body with soot particles is utilized. The measured impedance is in each case a measure of the soot charge of the particle filter and thus a measure of the state of the particle filter.

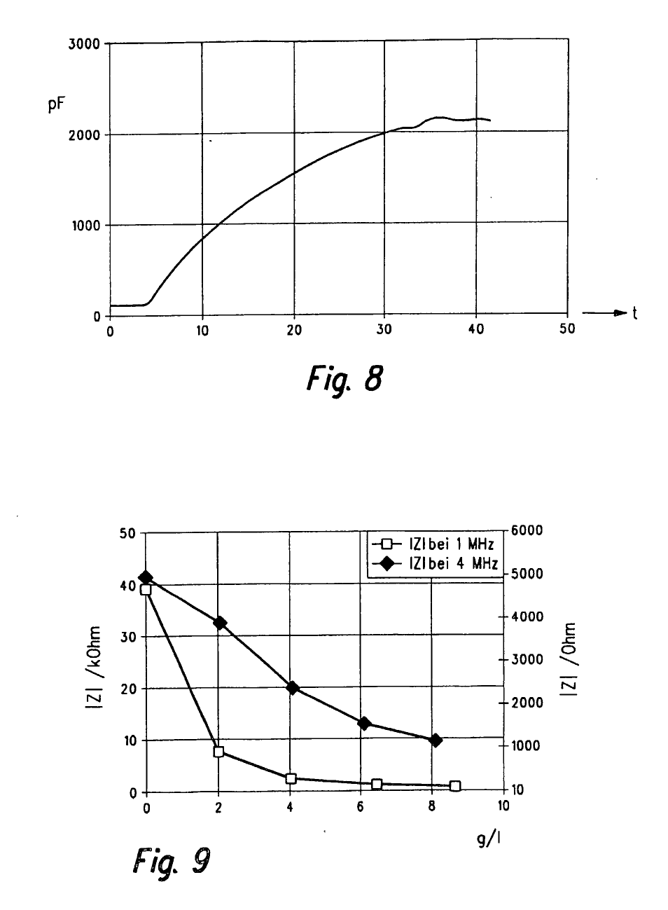

An impedance measuring device 24 (e.g., FIG. 13), which can also be embodied as a simple resistance measuring device, for example also as the DC resistance measuring device, is used to measure the impedance between the measuring electrodes 20, 21 and 22, 23. FIG. 7 shows that the resistance between the measuring electrodes decreases as the operating time t increases because soot particles which are still conductive collect between the measuring electrodes in the soot filter body 13. Correspondingly, FIG. 8 shows the capacitance between the measuring electrodes which changes as the soot charge grows, for the case in which the impedance measuring device 24 is embodied as a capacitance measuring device. Finally, FIG. 9 also shows the changing alternating current resistance for an increasing soot charge g/l (grams per liter volume) for two different measuring frequencies. The resistance measuring scale represented on the left-hand side applies for the measurement frequency 1 MHz, and the resistance measuring scale illustrated on the right-hand side applies for a measurement frequency of 4 MHz.

In addition to the absolute value of the electrical impedance, the phase of the electrical impedance can also be used as a measure of the soot-charged state of the soot particle filter.

The described measuring methods can of course also be used correspondingly for the soot sensor 16 and its measuring electrodes 18, 19.

In the embodiment illustrated in FIG. 2, the two pairs of electrodes with the measuring electrodes 20, 21 and 22, 23 are arranged one behind the other in the flow direction A. As a result, the soot particle charge can also be measured with spatial differentiation. The number of measuring electrodes used for this purpose can of course also be larger. In this context, these pairs of electrodes can also be arranged with an offset with respect to one another in the axial direction and in the radial direction, and can be arranged, for example, in a spiral shape. An alternative or additional arrangement on the end faces of the soot filter body 13 is also contemplated. In the simplest embodiment, it is, of course, also possible to provide just a single pair of electrodes.

Further possibilities for the provision of the measuring electrodes are illustrated in FIGS. 4 to 6. For example, FIG. 4 shows that two measuring electrodes 25, 26 can be arranged on two adjacent longitudinal sides of the soot filter body 13. FIG. 5 shows that two measuring electrodes 27, 28 can be arranged on different blind ducts 14, and FIG. 6 shows that two measuring electrodes 29, 30 can be arranged opposite one another on one of the blind ducts 14. In these illustrated embodiments, a plurality of pairs of electrodes can also be arranged one behind the other in the flow direction A, in which case combinations of the illustrated arrangements are also possible.

The measurement signal for the soot particle charge of the soot filter body 13 or of the ceramic substrate 17 is temperature-dependent. For this reason, for the purpose of compensation the temperature has to be measured by at least one temperature sensor, in which case the temperature measurement signal is then used to compensate the characteristic curves and measurement results illustrated in FIGS. 7 to 9. Such a temperature sensor can be arranged, for example, at any desired location in the soot filter body 13, but it can also be integrated, for example, in or on one of the measuring electrodes, for example in the form of a printed-on thick-film metal resistor. It is also contemplated in this context for the sensor to be a printed-on electrical conductor structure, or a measuring electrode or a plurality of measuring electrodes can be in the shape of an electrical conductor track whose resistance value depends on the temperature. The resistances of the measuring electrodes themselves are then a measure of the temperature, and the impedances between the measuring electrodes are a measure of the filter state or the charge of the filter with soot. Another possibility is for the temperature sensor to be arranged under a measuring electrode, separated by an insulation layer. In the case of the soot sensor 16, the temperature sensor can also be arranged on the rear side of the ceramic substrate 17 or also be arranged under the measuring electrodes 18, 19, separated by a dielectric.

The obtained measured values or the measurement curves shown in FIG. 7 to 9 can also be used for automatic regeneration of the soot particle filter. For this purpose, limiting values can be formed for the resistance or the capacitance or impedance, the regeneration of the filter being triggered automatically after the limiting values are reached. This is usually carried out by changing the engine operating state so that relatively hot exhaust gases are formed and burn off the soot particles which are deposited in the soot particle filter. This regeneration process changes the resistance values or capacitance values and/or impedance values in the rear direction and new limiting values at which the regeneration process is ended can be set.

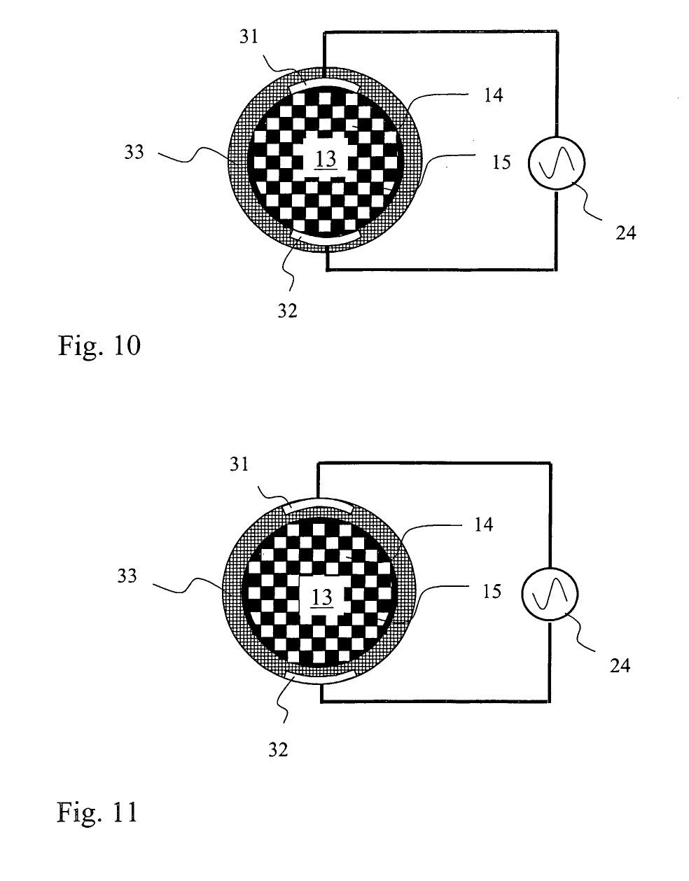

FIG. 10 illustrates a soot particle filter 13 in a cross section of the gas inlet side. Here, components which correspond to those in FIG. 1 are provided with the same reference symbols. The soot particle filter 13 is installed in the housing (not illustrated here) and is secured mechanically in the housing by a mounting mat 33 which surrounds the soot particle filter 13.

According to the invention, a measuring arrangement for the soot particle filter 13 is provided with a first measuring electrode 31 and a second electrode 32 with which the charge of the soot particle filter 13 can be determined. Here, the measuring electrodes 31, 32 are preferably of planar configuration and are arranged opposite one another. In this context, the measuring electrodes 31, 32, or one of them, can be arranged in the interior of the soot particle filter 13. Details are given below on advantageous arrangements in which the measuring electrodes 31, 32 are arranged on the outer surface of the soot particle filter 13 or at a short distance from the outer surface of the soot particle filter 13.

FIG. 10 illustrates an embodiment in which the electrodes 5, 6 are arranged diametrically opposite one another resting directly on the outer surface of the soot particle filter 13. The measuring electrodes 31, 32 form in this way the plates of a plate capacitor whose dielectric is formed by the material which is located between the measuring electrodes 31, 32. There is provision for the impedance measuring device 24 to be used both for supplying the voltage and current and for evaluating the measurement signal.

The electrical impedance which is effective in the partial volume region of the soot particle filter 13 between the measuring electrodes 31, 32 is dependent, on one hand, on the area of the measuring electrodes 31, 32 and on the distance between them, i.e., the diameter of the soot particle filter 13 at the respective location. On the other hand, however, the impedance is also dependent on the dielectric constant of the material located between the measuring electrodes 31, 32. Owing to the comparatively high dielectric constant of soot deposited in the soot particle filter 13, the soot charge in the volume region measured by the impedance measurement can be measured with high accuracy. There is provision here for the electrical impedance to be evaluated both with respect to its virtual part and to its real part and in terms of absolute value and phase. The aforesaid measurement variables are referred to below as a measurement signal for the sake of simplification. In this context, the evaluation of the measurement signal can be performed by the impedance measuring arrangement 24 or by a separate evaluation device (not illustrated).

In this context it is advantageous for the measurement frequency for determining the impedance to be suitably selected, and if appropriate varied, with the aim of obtaining the largest possible measurement signal and the most reliable possible information about the charge. The frequency of the measurement voltage is advantageously set in the range between 1 kHz and approximately 30 MHz. A frequency range from approximately 1 kHz to approximately 20 MHz is preferred, and the measurement frequency is particularly preferably approximately 10 MHz. It is also advantageous to perform simultaneous measurements of the temperature in the most significant soot particle filter region or in the region of the measuring electrodes 31, 32. As a result, temperature dependencies of the impedance measured value can be corrected or a temperature compensation of the measurement signal can be performed.

The measuring electrodes 31, 32 can, for example, be provided on the surface of the soot particle filter 13 by way of thick film technology or else by an electrically conductive material being sprayed or painted on. It is also advantageous to apply metal-containing films with the filter body, for example by sintering in close contact. The measuring electrodes 31, 32 can also be secured positionally on the filter body by the pressing force of the mounting mat 33 which occurs in the installed state.

FIG. 11 illustrates a further advantageous arrangement in which the functionally identical components to those in FIG. 10 are provided with the same reference symbols. In contrast to the arrangement illustrated in FIG. 10, the measuring electrodes 31, 32 according to FIG. 11 are not arranged directly in contact with the soot particle filter 13 but rather at a short distance from the surface of the soot particle filter 13. For example, owing to the low thermal loading it may be advantageous to arrange the measuring electrodes 31, 32 in the outer region of the mounting mat 33, or to embed them in the mounting mat 33. Depending on the thickness of the mounting mat 33, the measuring electrodes 31, 32 are typically arranged at a distance in the millimeter range from the surface of the particle filter body. For this arrangement it is advantageous to construct the measuring electrodes 31, 32 in film form.

According to the present invention, at least two, and preferably more, measuring electrodes 31, 32 can be provided at different locations, which permits the charge in the soot particle filter 13 to be determined with spatial resolution. The partial volume regions which are measured by the impedance measurement can overlap here or be separated from one another. In this way, the charge of the soot particle filter 13 can be determined locally. Depending on the size of the soot particle filter 13 and after the aimed-at spatial resolution, three, four or more electrode arrangements can be arranged, preferably in the direction of flow of the exhaust gas with an offset. Since in particular the outflow end region of the soot particle filter 13 is susceptible to blockage, it is advantageous when there are a plurality of measured partial volume regions to arrange them increasingly densely in the direction of flow of the exhaust gas, which improves the accuracy of the determination of the charge.

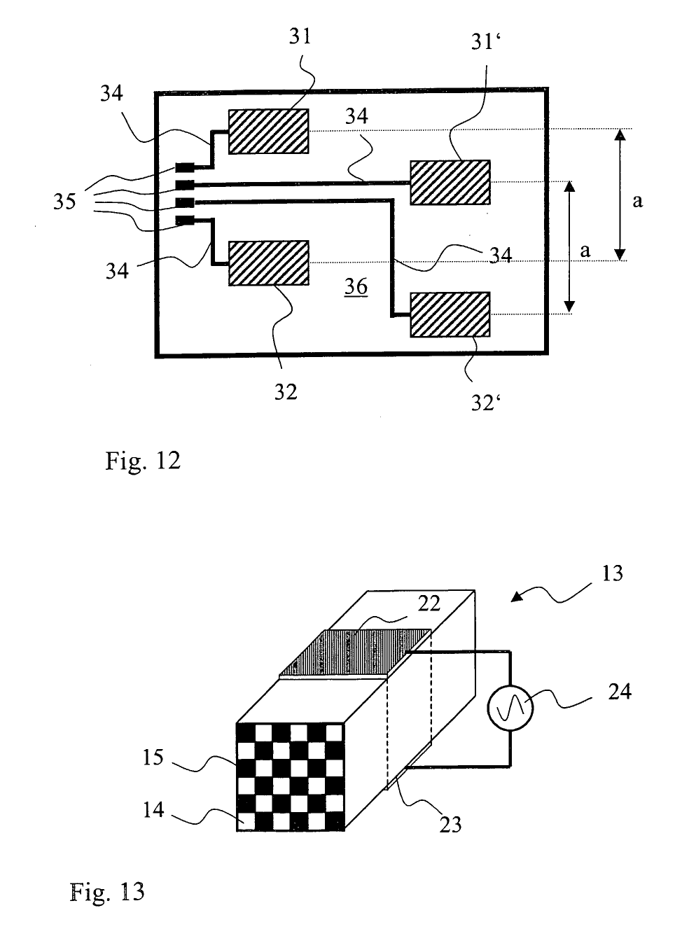

FIG. 12 is illustrates an electrode arrangement of two pairs of electrodes 31, 32 and 31′, 32′ developed onto a plane. The electrodes 31, 32 and 31′, 32′ are preferably applied as a layer on a thin and flexible carrier 36 which is mounted resting on the soot particle filter 13 or on the mounting mat 33. Feed lines 34 to the electrodes 31, 32 and 31′, 32′ are provided on the carrier 36 and lead to connecting contacts 35 which are preferably arranged at an end region of the carrier 36. This thus easily permits connection to the impedance measuring device 24 by a plug contact or clamping contact (not illustrated). This arrangement additionally has the advantage that only a single through-contact with the housing which surrounds the soot particle filter 13 has to be implemented for the connection to the impedance measuring device 24.

It is advantageous to arrange the electrodes 31, 32 and 31′, 32′ at a distance A on the carrier 36 with respect to their central longitudinal axis, which distance a corresponds approximately to half the circumference of the soot particle filter 13. In this way, in the mounted state of the carrier 36 the electrodes 31, 32 and 31′, 32′ are arranged approximately diametrically opposite one another. In addition, it is advantageous to arrange the electrodes 31, 32 and 31′, 32′ on the carrier 36 with an offset in the lateral or longitudinal direction of the carrier 36.

FIG. 13 illustrates a detail of a segment of a soot particle filter 13. Here, the components which correspond to those in FIG. 3 are identified by the same reference symbols.

The soot particle filter 13 is provided with a measuring arrangement with an electrode structure which can be used to determine the charge of the soot particle filter 13. Here, the electrode structure is formed by way of example by a first, approximately rectangular, planar electrode 22, and a second electrode 23 which is arranged diametrically opposite the latter and has the same shape. The electrodes 22, 23 are preferably arranged as illustrated in such a way that the imaginary connecting line which extends between their respective center points is oriented perpendicularly with respect to the longitudinal direction of the ducts 14, 15 of the soot particle filter 13. The electrodes 22, 23 thus form the end faces of a coherent, approximately cylindrical partial volume region of the soot particle filter 13, this partial volume region having an approximately rectangular cross section overall here. The longitudinal dimensions of the cylindrical partial volume region correspond here to the lateral dimensions of the soot particle filter 13 or of the filter segment, and the electrodes 22, 23 each rest on the outside of the particle filter. The electrodes 22, 23 in this way form the plates of a plate capacitor whose dielectric is formed by the material located between the electrodes 22, 23.

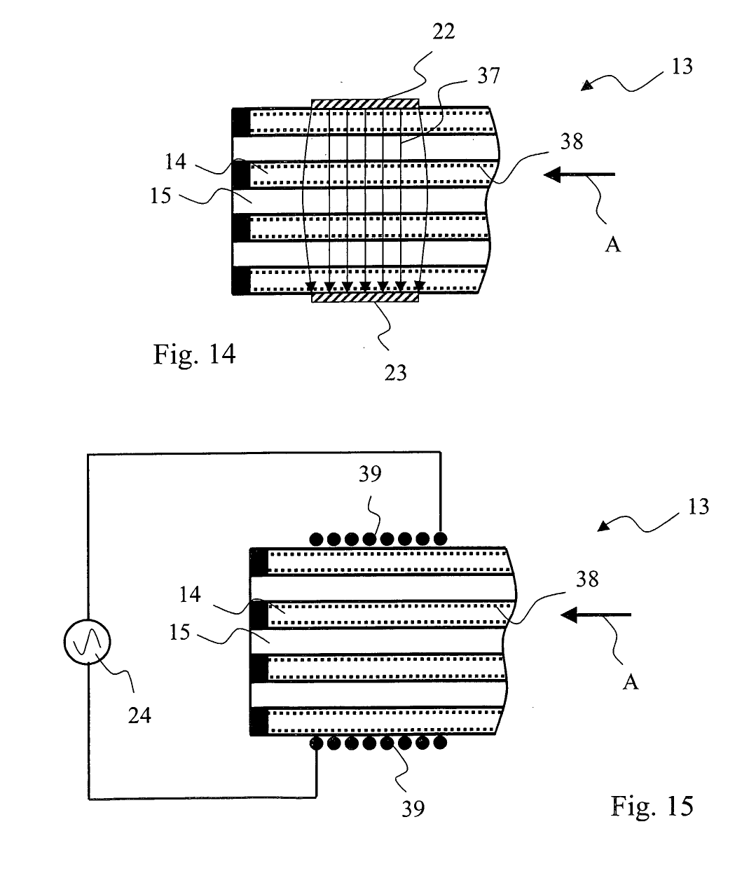

The above is illustrated once more in FIG. 14, and the impedance measuring device 24 and the associated feed lines have not again been illustrated. In addition, the soot and/or ash charge 38 which is present on the inside of the blind ducts 14 and is usually in layer form is illustrated schematically.

It is advantageous to use a soot particle filter 13 which is composed of a plurality of segments which are connected in parallel in terms of flow. Here, particle filter segments with a rectangular or square cross section are preferred. In total, external rounding of a soot particle filter which is composed of individual segments still makes it possible to obtain a filter body with a round or oval cross section. The individual segments are connected to one another mechanically in a flush fashion using a partially elastic joining compound. In this configuration, it is advantageous to provide the electrodes 22, 23 at the joint between the two respectively abutting segments so that they rest on the outside of a respective segment and are surrounded by the joining compound. A partial volume region of the soot particle filter 13 which is measured by the measuring arrangement can, with the described measuring arrangement, also be arranged completely in the interior of the filter body and surrounded by particle filter material. In the way described above, a dependence of the filter charge in the radial direction can be determined with respect to the flow direction A of flow of the exhaust gas.

According to the invention, the electrical capacitance or the complex electrical impedance of the capacitor which is formed via the electrodes 22, 23 is determined by the impedance measuring device 24. Here, the symbolic field lines 37 represent in schematic form the partial volume region, measured via the impedance measurement, of the soot particle filter 13.

In the device illustrated in FIG. 15, a soot particle filter 13 is shown with a measuring arrangement with a coil 39 as the conductor structure, with which the charge of the soot particle filter 13 can be determined. The windings of the coil 39 surround a section of the soot particle filter 13. The windings of the coil 39 preferably rest on the surface of the soot particle filter 13 or are at a short distance from it.

The measuring arrangement also comprises an impedance measuring device 24 which is connected to the coil 39 by feed lines. The coil 39 is supplied with a measurement voltage, preferably in the form of an alternating voltage, via the impedance measuring device 24. The section of the soot particle filter 13 which is surrounded by the coil 39 forms the core of the coil, for which reason its inductance L is determined essentially by the material acting as the coil core, or its permeability constant μr. Owing to the different permeability constants μr of soot and of mineral-like ashes, the soot charge and the ash charge can be differentiated by the measured inductance L in this context. The measured inductance here is linked to the complex electrical impedance of the conductor structure 39 and there is provision to evaluate the latter with respect to its virtual part and/or its real part or according to its absolute value and phase. In addition to the inductance L, the electrical losses, such as the ohmic losses or eddy current losses, can also be measured and evaluated. With respect to the aforesaid measurement variables, the term measurement signal is used below for the sake of simplification. There is provision for the impedance measuring device 24 to be used both for supplying the voltage and current and for evaluating the measurement signal. However, the measurement signal can also be evaluated by a separate measuring device.

In this context it is advantageous, when determining the inductance, to suitably select and if appropriate vary, the measurement frequency with the aim of obtaining the largest possible measurement signal and the most reliable possible information about the charge. The frequency of the measurement voltage is preferably set in the range between 1 kHz and approximately 30 MHz. A frequency range from approximately 100 kHz to approximately 10 MHz is preferred, and the measurement frequency is particularly preferably approximately 1 MHz. The amplitude of the supply voltage which is applied to the coil 39 by the impedance measuring device 24 is preferably selected in a range between 1 V and 1000 V. Since the inductance L of the coil 39 is also dependent on its geometry or number of turns, the sensitivity can also be suitably adapted by adapting these variables. It is also advantageous simultaneously to measure the temperature in the most significant filter region or in the region of the conductor structure 39 in order to be able to correct temperature dependencies of the inductance measured value or impedance measured value.

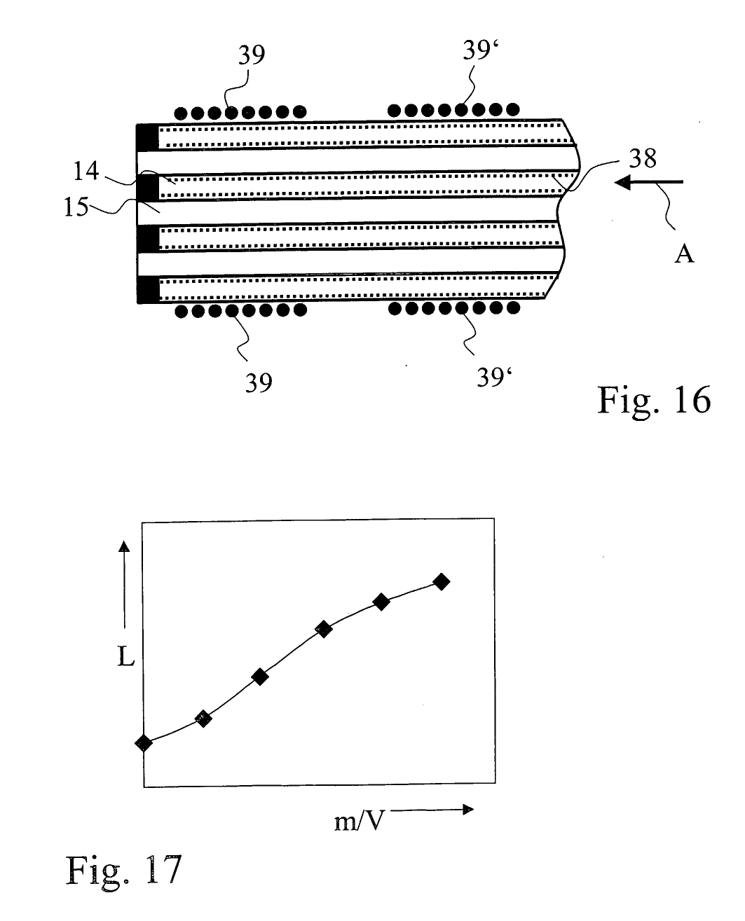

At least two coil-shaped conductor structures can be placed at different locations, which permits the charge in the soot particle filter 13 to be determined with spatial resolution. FIG. 16 is a schematic illustration of an arrangement with a first coil 39 and a second coil 39′ which is arranged opposite it with an axial offset with respect to the particle filter. For reasons of clarity, the impedance measuring device and the feed lines to the coils 39, 39′ are not also illustrated. Functionally identical components to those in FIG. 15 are provided with the same reference symbols. As a result of the offset arrangement of the coils 39, 39′, the charge of the soot particle filter 13 can be determined locally. Depending on the size of the soot particle filter 13 and according to the aimed-at spatial resolution, three, four or more conductor structures can be arranged, preferably with an offset with respect to one another, in the direction of the exhaust gas flow. Since in particular the outflow end region of the soot particle filter 13 is susceptible to blocking, at least one conductor structure is advantageously arranged at the outflow region of the soot particle filter 13.

As well as directly winding the coil-shaped conductor structure 39 around the filter body, further arrangements, which are obtained through simple modifications and are therefore not illustrated in more detail, are contemplated within the scope of the claimed invention. For example, the conductor structure 39 can be in the form of a coil on the internal surface of a housing which surrounds the soot particle filter 13. Furthermore a coil-shaped conductor structure can be advantageously arranged completely in the interior of the soot particle filter 13 parallel to or else transversely with respect to the flow direction A of the exhaust gas. An overlapping arrangement of coils with different diameters permits a coupled coil arrangement with a predefinable coupling to be provided.

When there are a plurality of coils which, in particular, are arranged with an offset with respect to one another, a variable which correlates to the mutual inductance of a coil can be advantageously measured, for example the mutual inductance of a coil with respect to another coil, and evaluates with respect to the filter charge. In one particularly advantageous embodiment (also not illustrated), three coils are arranged one behind the other in the direction of the exhaust gas flow and are, for example, wound around the filter body or surround volume regions of the filter body which lie one behind the other. The central coil can be operated as a transmitter, while the two other coils are respectively operated as receivers for the magnetic field induced in them by the central coil. With such an arrangement, asymmetries with respect to the axial distribution of the filter charge can be advantageously arranged. In this way, an ash charge or filter blockage which originates for the most part from the outflow side of the soot particle filter can be detected and evaluated.

In order to clarify the measuring effect which is measured by means of a measuring arrangement according to FIG. 15, FIG. 17 illustrates the measured inductance L of a coil 39 is illustrated as a function of the volume-related soot charge m/V of the particle filter. The soot-particle-containing exhaust gas of a diesel engine has been applied to the soot particle filter 13 and the measuring arrangement shown in FIG. 15 has been operated continuously under conditions which are close to reality. In this context, inductance values L in the region of several micro-Henrys have been measured for soot charges m/V in the range from several grams of soot per liter filter volume. As is apparent from FIG. 17, the dependence of the inductance L which is evaluated as a measurement signal on the soot charge m/V is approximately linear so that the charge state of the soot particle filter 13 can be determined reliably. The change in inductance which occurs owing to the filter charge can be determined, for example, by the change in the resonant frequency of an oscillatory circuit, which change is determined by the inductance of the conductor structure 39.

The above-explained devices make it is possible to measure accumulations of soot with spatial resolution, and regeneration of the soot particle filter can be initiated if the soot charge exceeds a predefinable limiting value in at least one of the measured partial volume regions. This prevents the soot particle filter being charged locally with soot beyond a permissible minimum degree, and as a result being destroyed at this location by excessive release of heat when regeneration is carried out through the burning off of soot. Of course, regeneration is also triggered if it is detected that the integral overall charge of the soot particle filter exceeds a predefinable threshold value. In addition it is advantageous, if appropriate, to adapt the limiting value which triggers the regeneration in order, for example, to react to changing regeneration conditions. This avoids an unacceptable rise in the counterpressure caused by the particle filter charge. The triggering of the particle filter regeneration in a way which is matched to requirements and adapted to the actual soot charge, limits the number of regeneration processes to a minimum and thus the thermal loading of the soot particle filter and of further exhaust gas cleaning units which may be present is kept low.

The limiting values for the local charge or the integral charge which are most significant for the triggering of regeneration are expediently stored in a control unit. The operation of a diesel engine is preferably controlled by this control unit and reset for regeneration of the soot particle filter. A person skilled in the art is familiar with operating modes which are suitable for this and they therefore do not require any further explanation here.

It is advantageous if the regeneration time of the soot particle filter is defined as a function of the local and/or integral charge, determined before the triggering of the regeneration, for example by a predefined characteristic-diagram-based regeneration time. In this context the temperature in the soot particle filter can be advantageously measured and the regeneration time defined as a function of previously stored soot burning-off rates for the respective temperature. The success of the regeneration is expediently checked by determining the charge again after the regeneration has ended. The predefined regeneration time can be appropriately corrected by evaluating a comparison between the determined charge before and after the regeneration. This avoids the operating state, which is necessary for the regeneration, being maintained for longer than necessary, and the expenditure of energy or additional consumption of fuel for the regeneration is thus kept small. In order to reliably define the duration of the regeneration process it is expedient here to perform averaging over the corresponding values before and after a plurality of regeneration processes.

It is particularly advantageous if the charge of the soot particle filter is also monitored during the regeneration process. The regeneration operating mode is then preferably maintained until the charge in each of the partial volume regions measured by the corresponding pairs of electrodes has dropped below a predefinable lower limiting value. This avoids incomplete particle filter regeneration processes and maximizes the absorption capacity of the soot particle filter for the subsequent normal operating mode of the diesel engine.

The determination of the particle filter charge in two or more partial volume regions of the soot particle filter is advantageously also used to differentiate between a soot charge component and an ash charge component. For this purpose, the fact that the measurement signal of a respective pair of electrodes is composed in an additive fashion from a component which is caused by the soot charge and a component which is caused by the ash charge, and the ash charge grows continuously is utilized. Although the contribution of the ash charge to the overall measurement signal is small, the ash charge component can, if appropriate, be determined if the time profile of the measurement signal is measured and a signal component which grows continuously within the course of the period of use of the soot particle filter 13 is determined and taken into account. In this context it is also advantageous to vary the measurement frequency.

In particular when the ash charge forms a very small component of the measurement signal, the ash charge is advantageously determined indirectly by evaluating the measurement signal in terms of its time profile and spatial profile. In particular, on the basis of the possibly different profile of the measurement signal, to what extent part of the soot particle filter has a greater soot charge than another can be determined, or whether only a small degree of soot charge, or none at all, occurs due to a high degree of deposition of ash in a partial volume region.

Since the absorption capacity for soot particles drops as the ash charge increases, it is advantageous to adapt or define the duration of the regeneration process and/or the time intervals between two regeneration processes as a function of the determined ash charge.

Specifically total blockage as a result of deposition of ash can be determined if there is no further accumulation of soot in one of the measured partial volume regions of the soot particle filter, that is an at least approximately stable measurement signal is present. In particular, when the charge is measured in a multiplicity of regions of the soot particle filter a degree of filling with ash can be determined with respect to the overall volume of the soot particle filter. As a result, the possibility of such particle filter becoming unusable owing to an excessive ash charge can be detected in good time and an appropriate warning message can be issued. It is advantageous in this context to carry out a predictive calculation about the further profile of the deposition of ash and to issue a warning message if the remaining residual running time up to the point when the soot particle filter becomes unusable drops below a predefinable value.

In the case of a wall flow filter, the filter may also become unusable owing to a stopper breakage. As a result, there is no longer any filter effect in the respective region. This can advantageously be detected by a separate soot sensor arranged downstream of the soot particle filter. However, this type of damage can also be detected if there is no longer any appreciable rise in the charge in a respective region over a predefinable time period. There is also provision for a fault message to be issued for this type of damage.

A further improvement in the reliability when the charge state is determined and when the soot particle filter is operated is obtained if, in addition to the measuring arrangement according to the invention, a pressure sensor or differential pressure sensor is used to measure the ram pressure upstream of the soot particle filter. The charge of the particle filter is also characterized on the basis of the corresponding pressure signal. Pressure sensors and signal evaluation methods with which a person skilled in the art is familiar can be used for this, for which reason further information in this regard can be dispensed with.

The pressure sensor permits the reliability and efficiency of the operation of the particle filter to be improved further. It is advantageous for this, for example, to subject the particle filter charge which is determined by the impedance measuring device to checking, plausibility checking or correction by means of the pressure signal. It is advantageous, for example, to use an interrelation of the manner of a cross-correlation to reconcile the values obtained from the measurement signals of the impedance measuring device for the soot charge or for the charge limiting values which are most significant for the process of particle filter regeneration if appropriate with the pressure signal values, or to correct them. The additional pressure sensor can also be used to carry out diagnostics of the impedance measuring device in order to detect faults or defects and if appropriate indicate them.

1-28. (canceled)

29. A device for determining the state of a soot particle filter of an internal combustion engine, comprising an electrical measuring arrangement configured as a soot sensor for measuring a soot deposit of the soot particle filter, including an electrical component with a conductor structure for exciting an electrical or magnetic field influenceable by the soot deposit and characterizes an electrical or magnetic characteristic variable of the component as a measure of a quantity of the soot deposit, wherein the conductor structure is arranged such that a partial volume region of the soot particle filter is penetrated by the electrical field and the partial volume region forms part of the component, and the electrical component is a coil or a capacitor.

30. The device as claimed in claim 29, wherein the soot deposit is measurable in partial volume regions of the soot particle filter that are different from one another.

31. The device as claimed in claim 29, wherein the measuring means measures a characteristic variable of the component which is linked to the electrical impedance.

32. The device as claimed in claim 31, wherein at least one of the absolute value and phase of the electrical impedance is measurable.

33. The device as claimed in claim 31, wherein at least one of the ohmic resistance, the capacitance and the inductance of the component is measurable.

34. The device as claimed in claim 32, wherein at least one of the ohmic resistance, the capacitance and the inductance of the component is measurable.

35. The device as claimed in claim 29, wherein switching means are provided for automatically initiating regeneration of the filter when a predefinable triggering measured value is reached.

36. The device as claimed in claim 29, wherein switching means are provided for automatically ending the regeneration of the filter when a predefinable limiting measured value is reached.

37. The device as claimed in claim 29, wherein means are provided for at least one of measuring the temperature of the filter and performing temperature compensation on the measurement signal.

38. The device as claimed in claim 29, wherein a coil-shaped conductor structure is arranged at least partially in the interior of the soot particle filter.

39. The device as claimed in claim 29, wherein a coil-shaped conductor structure is arranged outside the soot particle filter.

40. The device as claimed in claim 38, wherein the soot particle filter is of cylindrical configuration, and a coil longitudinal axis of the coil-shaped conductor structure is oriented one of approximately parallel and approximately perpendicular to a longitudinal axis of the soot particle filter.

41. The device as claimed in claim 39, wherein the soot particle filter is of cylindrical configuration, and a coil longitudinal axis of the coil-shaped conductor structure is oriented one of approximately parallel and approximately perpendicular to a longitudinal axis of the soot particle filter.

42. The device as claimed in claim 38, wherein the measuring arrangement further comprises a second conductor structure, the coil-shaped conductor structure being operatively connected to the second conductor structure which has an electrical characteristic variable influenceable by the soot deposit and measurable by the measuring means.

43. The device as claimed in claim 42, wherein the measuring arrangement further comprises a second conductor structure, the coil-shaped conductor structure being operatively connected to the second conductor structure which has an electrical characteristic variable influenceable by the soot deposit and measurable by the measuring means.

44. The device as claimed in claim 42, wherein the second conductor structure is a second coil-shaped conductor structure, and a variable which correlates to the mutual inductance which is effective between the coil-shaped conductor structures is measurable by the measuring means.

45. The device as claimed in claim 43, wherein the second conductor structure is a second coil-shaped conductor structure, and a variable which correlates to the mutual inductance which is effective between the coil-shaped conductor structures is measurable by the measuring means.

46. The device as claimed in claim 42, wherein the coil-shaped conductor structure is arranged in an exhaust gas flow direction with an offset with respect to the second conductor structure.

47. The device as claimed in claim 43, wherein the coil-shaped conductor structure is arranged in an exhaust gas flow direction with an offset with respect to the second conductor structure.

48. The device as claimed in claim 44, wherein the coil-shaped conductor structure is arranged in an exhaust gas flow direction with an offset with respect to the second conductor structure.

49. The device as claimed in claim 44, wherein the coil-shaped conductor structure is arranged in an exhaust gas flow direction with an offset with respect to the second conductor structure.

50. The device as claimed in claim 29, wherein the conductor structure comprises a pair of electrodes with a first electrode and a second electrode spaced from the first electrode, the partial volume region being arranged between the first electrode and the second electrode.

51. The device as claimed in claim 50, wherein at least the first electrode and the second electrode is arranged on or a short distance from an outer surface of the soot particle filter.

52. The device as claimed in claim 50, wherein the measuring arrangement further comprises at least two pairs of electrodes.

53. The device as claimed in claim 51, wherein the measuring arrangement further comprises at least two pairs of electrodes.

54. The device as claimed in claim 52, wherein the first pair of electrodes is arranged in the exhaust gas flow offset from the second pair of electrodes.

55. The device as claimed in claim 53, wherein the first pair of electrodes is arranged in the exhaust gas flow offset from the second pair of electrodes.

56. The device as claimed in claim 29, further comprising a second electrical measuring arrangement operative as a soot sensor for measuring a soot deposit is arranged downstream of the soot particle filter with respect to a flow direction through the soot particle filter.
